(19) United States
(12) Patent Application Publication
(10) Pub. No.: US 2011/0255378 A1
(43) Pub. Date: Oct. 20, 2011

(54) PACKAGE MANUFACTURING METHOD, PIEZOELECTRIC VIBRATOR, OSCILLATOR, ELECTRONIC DEVICE, AND RADIO-CONTROLLED TIMEPIECE

(76) Inventors: Yoichi Funabiki, Chiba-shi (JP); Masashi Numata, Chiba-shi (JP); Kazuyoshi Sugama, Chiba-shi (JP)

(21) Appl. No.: 13/170,877

(22) Filed: Jun. 28, 2011

Related U.S. Application Data
(63) Continuation of application No. PCT/JP2009/053334, filed on Feb. 25, 2009.

(51) Int. Cl. G04C 11/02; H03B 5/36; H01L 41/22; H01L 41/053

(52) U.S. Cl. 368/47; 310/344; 331/158; 29/25.35

(57) ABSTRACT

A method of manufacturing a package capable of sealing an electronic component in a cavity formed between a plurality of substrates bonded to each other includes a penetration electrode forming step of forming a penetration electrode which passes through a first substrate of the plurality of substrates in the thickness direction and which electrically connects the inside of the cavity and the outside of the package to each other. The package manufacturing method is characterized in that the penetration electrode forming step includes a through hole forming step of forming a through hole for disposing the penetration electrode in the first substrate and a filling step of filling a filler into the through hole under a decompressed atmosphere.

### RELATED APPLICATIONS

This application is a continuation of PCT/JP2009/053334 filed on Feb. 25, 2009. The entire content of this application is incorporated herein by reference.

### BACKGROUND OF THE INVENTION

1. Field of the Invention

The present invention relates to a package manufacturing method, a piezoelectric vibrator, an oscillator, an electronic device, and a radio-controlled timepiece.

2. Description of the Related Art

In recent years, piezoelectric vibrators using crystal or the like have been used in mobile phones or portable information terminals as a time source, a timing source of a control signal or the like, a reference signal source, and the like. Various piezoelectric vibrators are known as such kinds of piezoelectric vibrators, and a surface mount (SMD) type piezoelectric vibrator is known as one type of piezoelectric vibrator. This kind of piezoelectric vibrator includes a base substrate (first substrate) and a lid substrate (second substrate) bonded to each other, a cavity formed between both substrates, and a piezoelectric vibrating reed (electronic component) housed in the cavity in an airtight sealed state, for example.

This type of piezoelectric vibrator has a two-layer structure by direct bonding of the base substrate and the lid substrate, and the piezoelectric vibrating reed is housed in the cavity formed between both substrates.

As one of such two-layer structure type piezoelectric vibrators, a piezoelectric vibrator is known in which a piezoelectric vibrating reed and an external electrode formed on a base substrate are electrically connected to each other using a conductive member formed to pass through the base substrate (for example, refer to Patent Citations 1 and 2).

This piezoelectric vibrator 200 includes a base substrate 201 and a lid substrate 202, which are anodic-bonded to each other with a bonding film 207 interposed therebetween, and a piezoelectric vibrating reed 203 sealed in the cavity C formed between both substrates 201 and 202, as shown in FIGS. 24 and 25. The piezoelectric vibrating reed 203 is a tuning fork type vibrating reed, for example, and is mounted on the top surface of the base substrate 201 in the cavity C, with a conductive adhesive E interposed therebetween.

The base substrate 201 and the lid substrate 202 are insulating substrates formed of ceramic material, glass, or the like, for example. A through hole 204 passing through the substrate 201 is formed in the base substrate 201 of both substrates 201 and 202. Moreover, in this through hole 204, a conductive member 205 is embedded so as to block the through hole 204. This conductive member 205 is electrically connected to an external electrode 206 formed on the bottom surface of the base substrate 201 and is also electrically connected the piezoelectric vibrating reed 203 mounted in the cavity C.

### Patent Citation 1: JP-A-2002-121037

### Patent Citation 2: JP-A-2007-13628

Incidentally, in the two-layer structure type piezoelectric vibrator described above, the conductive member 205 plays two major roles of maintaining the airtightness in the cavity C by blocking the through hole 204 and of electrically connecting the piezoelectric vibrating reed 203 and the external electrode 206 to each other.

Here, as an example of the method of manufacturing the conductive member 205 described above, a method of filling conductive paste (Ag paste, AuSn paste, or the like) into the through hole 204 in the atmosphere and then curing it by baking may be considered.

However, if baking is performed after filling of conductive paste, an organic matter contained in the conductive paste disappears by evaporation. As a result, since the volume of the conductive paste after baking is reduced compared with that before the baking, there is a possibility that a recess will be generated on the surface of the conductive member 205 formed of conductive paste or a through hole will be open at its center in the worst case.

In order to solve the above-described problem, a method of forming a penetration electrode by disposing a metal pin in the through hole 204 and filling and baking a paste-state filler in a gap between the through hole 204 and the pin has been proposed. Since the volume reduction occurs only in a part of the paste material by forming the penetration electrode as described above, the end surface of the pin becomes even with the surface of the base substrate 201. As a result, an electrical connection between the penetration electrode and the external electrode 206 can be ensured without generating a gap between the penetration electrode and the external electrode 206 connected to the pin.

However, if the above-described filler is filled in the atmosphere, the following problems occur.

That is, if a filler is filled using a squeegee in a state where a pin is disposed in the through hole 204, the air in the atmosphere is pushed into the through hole 204 together with the filler and the through hole 204 is blocked by the filler. Accordingly, since the air in the through hole 204 cannot go out, there is a problem in that a sufficient amount of filler is not filled in the through hole 204.

In addition, bubbles present in the filler enter the through hole 204. This also causes a problem in that a sufficient amount of filler is not filled. In addition, since the bubbles evaporate by subsequent baking, the volume after baking is significantly reduced compared with that before the baking. For this reason, there is a possibility that a recess will be generated on the surface of the baked filler as described above.

As a result, there is a possibility that the airtightness in the cavity C would be influenced or an electrode film (for example, the external electrode 206) formed to cover the penetration electrode would be broken.

In addition, there is a problem in that the vibration characteristic of the piezoelectric vibrator 200 deteriorates if the air remaining in the through hole 204 leaks to the cavity C after baking of the filler.

### SUMMARY OF THE INVENTION

Therefore, the present invention has been made in view of the above-described problems, and it is an object of the present invention to provide a package manufacturing method capable of improving the yield by maintaining the airtightness in a cavity and ensuring an electrical connection between a piezoelectric vibrating reed and an external electrode, a piezoelectric vibrator, an oscillator, an electronic device, and a radio-controlled timepiece.

In order to solve the problems described above, the present invention provides the following means.

A package manufacturing method related to the present invention is a method of manufacturing a package capable of sealing an electronic component in a cavity formed between a plurality of substrates bonded to each other, and includes a penetration electrode forming step of forming a penetration electrode which passes through a first substrate of the plurality of substrates in the thickness direction and which electrically connects the inside of the cavity and the outside of the package to each other. The penetration electrode forming step includes a through hole forming step of forming a through hole for disposing the penetration electrode in the first substrate and a filling step of filling a filler into the through hole under a decompressed atmosphere.

According to this configuration, since the filler is degassed by performing the filling step under the decompressed atmosphere, bubbles included in the filler can be removed. As a result, bubbles are not present in the filler, and the air is not present in the through hole. Accordingly, when filling the through hole with a filler, the filler can be smoothly filled into the through hole compared with the case of filling the filler in the atmosphere as in the related art. As a result, it is possible to fill the through hole with the filler without a gap. Since the through hole can be sealed without a gap by baking the filler in this state, the airtightness in the cavity can be satisfactorily maintained. In addition, since a volume reduction or deformation tends not to occur in the filler after baking, a penetration electrode with a desired size can be disposed. Therefore, the external electrode comes in close contact with the penetration electrode without generating a gap therebetween. As a result, an electrical connection with an electrode film (for example, an external electrode) connected to an electronic component can be ensured through the penetration electrode.

In addition, since the air remaining in the through hole does not leak to the cavity after baking of the filler, the characteristic of the package does not deteriorate.

Accordingly, a small and highly reliable package can be manufactured with an improved yield.

In addition, the filling step includes: a first scanning step of scanning a first squeegee from one end side of the first substrate to the other end side along a top surface of the first substrate in order to fill the filler into the through hole; and a second scanning step of scanning a second squeegee from the other end side of the first substrate to the one end side along the top surface of the first substrate in order to remove the filler present outside the through hole. The ambient pressure in the second scanning step is set to be higher than that in the first scanning step.

Incidentally, if the filler is exposed for a long period of time under the extremely decompressed atmosphere, there is a possibility that components (for example, organic solvent) contained in the filler may be removed by evaporation. As a result, since the viscosity of the filler remaining outside the through hole is increased, it becomes difficult to remove the filler in the second scanning step.

In contrast, according to the configuration of the present invention, evaporation of components contained in the filler can be prevented by increasing the pressure in the chamber in the second scanning step compared with the first scanning step. Accordingly, since an increase in the viscosity of the filler can be prevented, the second scanning step can be smoothly performed.

In addition, before the filling step, a rivet body setting step of inserting a core portion of a conductive rivet body, which has a plate-shaped base portion and the core portion which extends along a direction perpendicular to a surface of the base portion, into the through hole so that the surface of the base portion is in contact with a bottom surface of the first substrate is set. In the filling step, the glass frit is filled between the core portion and the through hole using paste-state glass frit as the filler. After the filling step, a baking step of baking the glass frit to integrally fix the through hole and the core portion and a polishing step of polishing the base portion and the bottom surface of the first substrate, on which the base portion is disposed, and polishing the top surface of the first substrate so that the core portion is exposed are set.

According to this configuration, since the volume reduction after baking occurs only in a part of the filler filled between the core portion and the through hole by disposing the conductive core portion in the through hole, the core portion becomes even with the surface of the first substrate. As a result, an electrical connection between the penetration electrode and the external electrode can be ensured without generating a gap between the penetration electrode and the external electrode connected to the core portion.

In addition, since the rivet body in which the core portion is formed on the base portion is used, it is possible to match the axial direction of the core portion to the axial direction of the through hole with a simple operation of pushing the base portion until the base portion comes in contact with the first substrate. Accordingly, the workability in the rivet body setting step can be improved. In addition, the first substrate is stabilized without shaking even if the first substrate is placed on a flat surface, such as a desk, until a baking step performed later. Also from this point of view, the workability can be improved.

In particular, according to the configuration of the present invention, since a through hole can be filled with glass frit without a gap, the through hole can be sealed without a gap by baking the glass fit thereafter. As a result, the airtightness in the cavity can be satisfactorily maintained. In addition, since a volume reduction or deformation after baking tends not to occur, the core portion can be firmly fixed at a predetermined position. As a result, since a high-quality penetration electrode can be formed, an electrical connection between an electronic component and an external electrode can be ensured.

Moreover, in the first scanning step, the viscosity of the glass frit is set to be equal to or larger than 10 Pa·s and equal to or smaller than 200 Pa·s.

According to this configuration, since the fluidity of the glass frit is improved by setting the viscosity of the glass frit to be equal to or larger than 10 Pa·s and equal to or smaller than 200 Pa·s, the filler can be smoothly filled into the through hole in the filling step.

Moreover, in the first scanning step, the scanning speed of the squeegee is set to be equal to or larger than 1 mm/sec and equal to or smaller than 50 mm/sec.

If the scanning speed of the squeegee is set to be smaller than 1 mm/sec, the above-described desired viscosity cannot be obtained. Therefore, this is not preferable as there is a possibility that the glass frit will not smoothly enter the through hole.

On the other hand, setting the scanning speed of the squeegee to be larger than 10 mm/sec is not preferable because it is difficult to make the glass frit enter the through hole.

In contrast, by setting the scanning speed of the squeegee to be equal to or larger than 1 mm/sec and equal to or smaller than 50 mm/sec, the glass frit can be set to have the desired viscosity described above. As a result, since the fluidity of the glass frit is improved, the filler can be smoothly filled into the through hole in the first scanning step.

Moreover, in the first scanning step, line pressure acting on the glass frit from the tip of each squeegee is set to be equal to or larger than 1 mg/mm and equal to or smaller than 1000 mg/mm.

According to this configuration, if the line pressure acting on the glass frit from the squeegee is set to be smaller than 1 mm/sec, the desired viscosity described above cannot be obtained. Therefore, this is not preferable as there is a possibility that the glass frit will not smoothly enter the through hole.

On the other hand, setting the pressing force to be larger than 1000 mg/mm is not preferable as the first substrate would be overloaded.

In contrast, by setting the line pressure acting on the glass frit from the squeegee to be equal to or larger than 1 mg/mm and equal to or smaller than 1000 mg/mm, the glass frit can be set to have the desired viscosity described above. As a result, since the fluidity of the glass frit is improved, the filler can be smoothly filled into the through hole in the first scanning step.

In addition, a piezoelectric vibrator related to the present invention is manufactured by the package manufacturing method of the present invention described above.

According to this configuration, since this is the piezoelectric vibrator manufactured by the package manufacturing method of the present invention described above, it is possible to provide a small and highly reliable piezoelectric vibrator.

In addition, there is provided an oscillator related to the present invention including the piezoelectric vibrator of the present invention described above, which is electrically connected to an integrated circuit, as a vibrator.

In addition, there is provided an electronic device related to the present invention including the piezoelectric vibrator of the present invention described above which is electrically connected to a timepiece section.

In addition, there is provided a radio-controlled timepiece related to the present invention including the piezoelectric vibrator of the present invention described above which is electrically connected to a filter section.

Since each of the oscillator, the electronic device, and the radio-controlled timepiece related to the present invention includes the above-described piezoelectric vibrator, it is possible to provide small and highly reliable products.

According to the method of manufacturing the piezoelectric vibrator related to the present invention, it is possible to fill a through hole with a filler without a gap. Since the through hole can be sealed without a gap by baking the filler in this state, the airtightness in the cavity can satisfactorily maintained. In addition, since a volume reduction or deformation tends not to occur in the filler after baking, a penetration electrode with a desired size can be disposed. Therefore, the external electrode comes in close contact with the penetration electrode without generating a gap therebetween. As a result, an electrical connection with an electrode film (for example, an external electrode) connected to an electronic component can be ensured through the penetration electrode.

In addition, since the air remaining in the through hole does not leak to the cavity after baking of the filler, the characteristic of the package does not deteriorate.

Accordingly, a small and highly reliable package can be manufactured with an improved yield.

In addition, according to the piezoelectric vibrator related to the present invention, it is possible to provide a small and highly reliable piezoelectric vibrator since this is a piezoelectric vibrator manufactured by the package manufacturing method of the present invention described above.

Since each of the oscillator, the electronic device, and the radio-controlled timepiece related to the present invention includes the above-described piezoelectric vibrator, it is possible to provide small and highly reliable products.

### BRIEF DESCRIPTION OF THE DRAWINGS

FIG. 1 is an appearance perspective view showing an embodiment of a piezoelectric vibrator related to the present invention.

FIG. 2 is a view showing the internal configuration of the piezoelectric vibrator shown in FIG. 1 when a piezoelectric vibrating reed is viewed from above with a lid substrate removed.

FIG. 3 is a sectional view of the piezoelectric vibrator taken along the line A-A shown in FIG. 2.

FIG. 4 is an exploded perspective view of the piezoelectric vibrator shown in FIG. 1.

FIG. 5 is a top view of a piezoelectric vibrating reed which forms the piezoelectric vibrator shown in FIG. 1.

FIG. 6 is a bottom view of the piezoelectric vibrating reed shown in FIG. 5.

FIG. 7 is a sectional view taken along the line B-B of FIG. 5.

FIG. 8 is a perspective view of a cylinder which forms a penetration electrode shown in FIG. 3.

FIG. 9 is a flow chart showing the flow when manufacturing the piezoelectric vibrator shown in FIG. 1.

FIG. 10 is a view showing one step when manufacturing a piezoelectric vibrator according to the flow chart shown in FIG. 9, and is a view showing a state where a pair of through holes is formed in a wafer for a base substrate which is the origin of a base substrate.

FIG. 11 is a sectional view taken along the line D-D of FIG. 10.

FIG. 12 is a perspective view of a rivet body.

FIG. 13 is a view showing one step when manufacturing a piezoelectric vibrator according to the flow chart shown in FIG. 9, and is a view showing a state where the rivet body is disposed in a through hole.

FIG. 14 is a view showing one step when manufacturing a piezoelectric vibrator according to the flow chart shown in FIG. 9, and is a view showing a state of filling glass frit.

FIG. 15 is a view showing one step when manufacturing a piezoelectric vibrator according to the flow chart shown in FIG. 9, and is a view showing a state where glass frit has been filled.

FIG. 16 is a view showing one step when manufacturing a piezoelectric vibrator according to the flow chart shown in FIG. 9, and is a view showing a state of removing superfluous glass frit.

FIG. 17 is a view showing one step when manufacturing a piezoelectric vibrator according to the flow chart shown in FIG. 9, and is a view showing a state where superfluous glass frit has been removed.

FIG. 18 is a view showing one step when manufacturing a piezoelectric vibrator according to the flow chart shown in FIG. 9, and is a view showing a state where glass frit has been baked.

FIG. 19 is a view showing one step when manufacturing a piezoelectric vibrator according to the flow chart shown in FIG. 9, and is a view showing a state where a base portion of the rivet body has been polished.

FIG. 20 is a view showing one step when manufacturing a piezoelectric vibrator according to the flow chart shown in FIG. 9, and is a view showing a state where a bonding film and a lead-out electrode are patterned on the top surface of the wafer for a base substrate.

FIG. 21 is a configuration view showing an embodiment of an oscillator related to the present invention.

FIG. 22 is a configuration view showing an embodiment of an electronic device related to the present invention.

FIG. 23 is a configuration view showing an embodiment of a radio-controlled timepiece related to the present invention.

FIG. 24 is a view showing the internal configuration of a conventional piezoelectric vibrator when a piezoelectric vibrating reed is viewed from above with a lid substrate removed.

FIG. 25 is a sectional view of the piezoelectric vibrator shown in FIG. 23.

### DETAILED DESCRIPTION OF THE PREFERRED EMBODIMENTS

Next, embodiments related to the present invention will be described on the basis of the drawings.

### (Piezoelectric Vibrator)

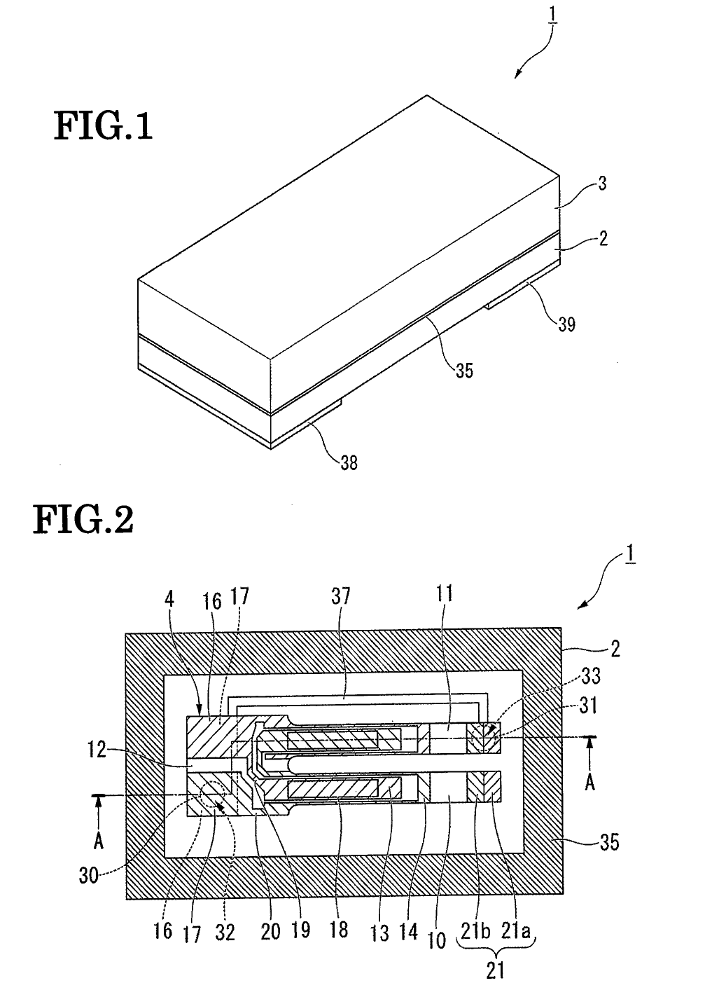

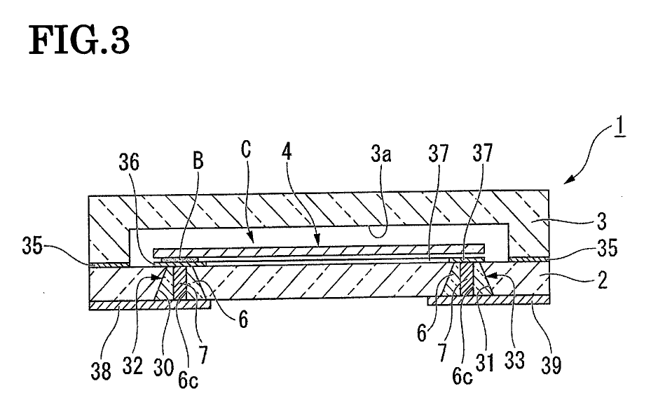

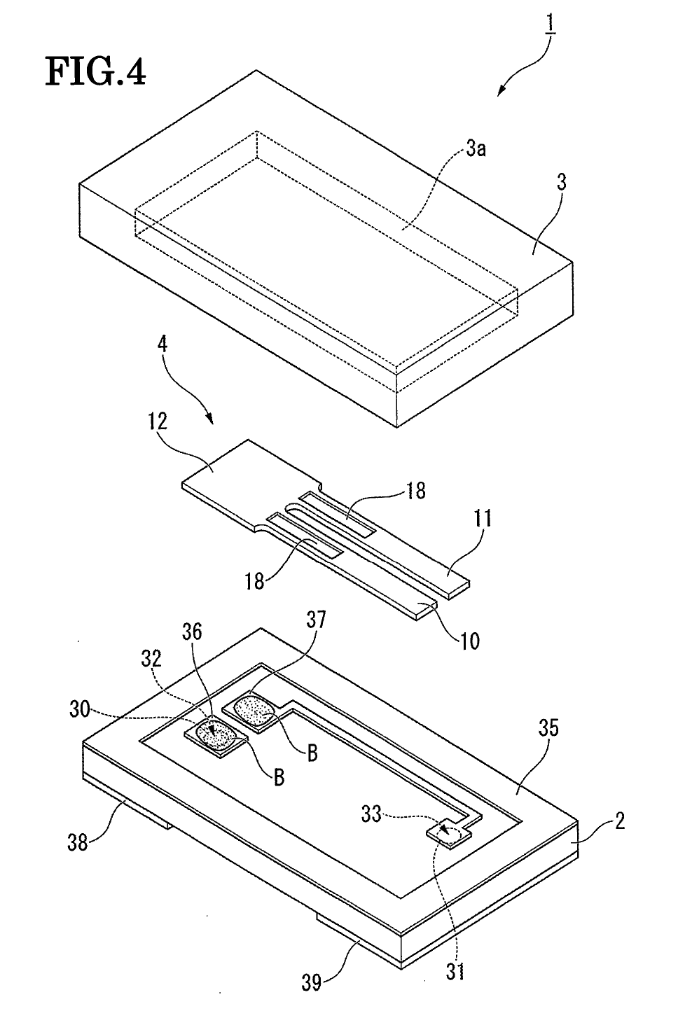

FIG. 1 is a perspective view showing the external appearance of a piezoelectric vibrator related to the present invention, and FIG. 2 is a view showing the internal configuration of the piezoelectric vibrator when a piezoelectric vibrating reed is viewed from above with a lid substrate removed. In addition, FIG. 3 is a sectional view of the piezoelectric vibrator taken along the line A-A shown in FIG. 2, and FIG. 4 is an exploded perspective view of the piezoelectric vibrator.

As shown in FIGS. 1 to 4, a piezoelectric vibrator 1 of the present embodiment is formed in a box shape in which two layers of a base substrate (first substrate) 2 and a lid substrate (second substrate) 3 are laminated, and is a surface mount type piezoelectric vibrator in which a piezoelectric vibrating reed 4 is housed in an internal cavity C (refer to FIG. 4). Moreover, for easy understanding of the drawings, an excitation electrode 15, lead-out electrodes 19 and 20, mount electrodes 16 and 17, and a weight metal film 21, which will be described later, are not shown in FIG. 4.

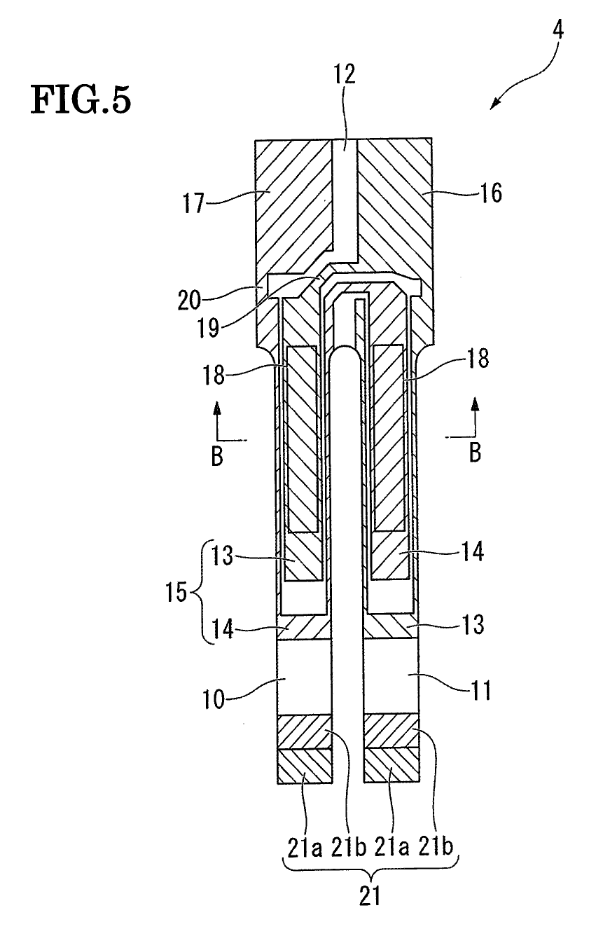

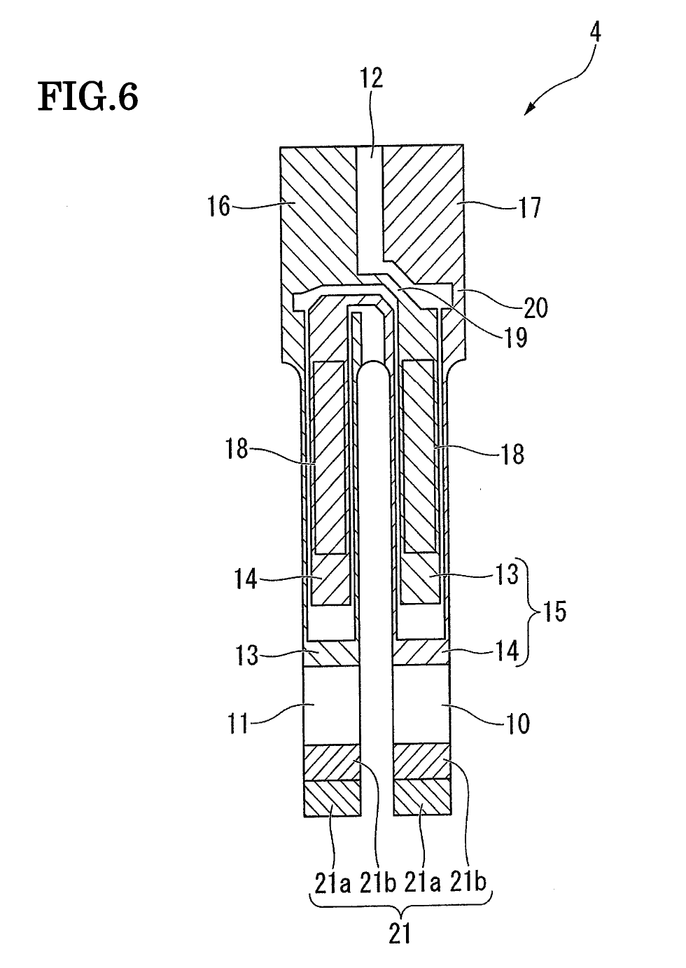

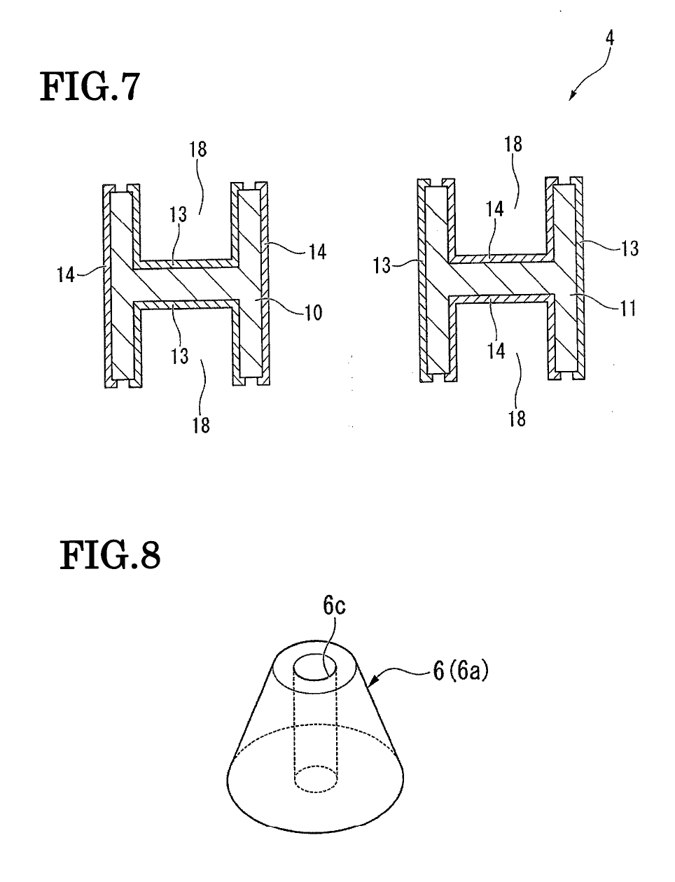

FIG. 5 is a top view of a piezoelectric vibrating reed which forms a piezoelectric vibrator, FIG. 6 is a bottom view, and FIG. 7 is a sectional view taken along the line B-B of FIG. 5.

As shown in FIGS. 5 to 7, the piezoelectric vibrating reed 4 is a tuning fork type vibrating reed formed of a piezoelectric material, such as crystal, lithium tantalate, or lithium niobate, and vibrates when a predetermined voltage is applied.

This piezoelectric vibrating reed 4 has: a pair of vibrating arms 10 and 11 disposed in parallel; a base portion 12 which integrally fixes the base end sides of the pair of vibrating arms 10 and 11; an excitation electrode 15 formed by first and second excitation electrodes 13 and 14 which are formed on the outer surfaces of the pair of vibrating arms 10 and 11 in order to vibrate the pair of vibrating arms 10 and 11; and mount electrodes 16 and 17 electrically connected to the first and second excitation electrodes 13 and 14.

In addition, the piezoelectric vibrating reed 4 of the present embodiment includes a groove 18 which is formed on each of both principal surfaces of the pair of vibrating arms 10 and 11 along the longitudinal directions of the vibrating arms 10 and 11. This groove 18 is formed from the base end sides of the vibrating arms 10 and 11 to the approximate middle.

The excitation electrode 15 formed by the first and second excitation electrodes 13 and 14 is an electrode which vibrates the pair of vibrating arms 10 and 11 at a predetermined resonance frequency in a direction moving closer to or away from each other, and is formed on the outer surfaces of the pair of vibrating arms 10 and 11 by patterning in an electrically isolated state.

In addition, the first and second excitation electrodes 13 and 14 are electrically connected to the mount electrodes 16 and 17 through the lead-out electrodes 19 and 20 on both the principal surfaces of the base portion 12, respectively.

In addition, the weight metal film 21 for adjusting (frequency adjustment) the vibrating states of the pair of vibrating arms 10 and 11 to vibrate within a predetermined frequency range is formed at the distal ends of the vibrating arms 10 and 11. In addition, this weight metal film 21 is divided into a rough adjustment film 21a, which is used when performing rough adjustment of a frequency, and a fine adjustment film 21b, which is used when performing fine adjustment of a frequency.

As shown in FIGS. 3 and 4, the piezoelectric vibrating reed 4 configured in this way is bump-bonded to the top surface of the base substrate 2 using a bump B made of gold or the like. More specifically, the piezoelectric vibrating reed 4 is bump-bonded in a state where the pair of mount electrodes 16 and 17 is in contact with two bumps B formed on lead-out electrodes 36 and 37, which are patterned on the top surface of the base substrate 2 and will be described later. As a result, the piezoelectric vibrating reed 4 is supported in a state floated from the top surface of the base substrate 2, and the mount electrodes 16 and 17 and the lead-out electrodes 36 and 37 are electrically connected to each other, respectively.

The lid substrate 3 is a transparent insulating substrate made of a glass material, for example, soda lime glass, and is formed in a plate shape as shown in FIGS. 1, 3, and 4. In addition, a rectangular recess 3a in which the piezoelectric vibrating reed 4 is housed is formed at the bonding surface side to which the base substrate 2 is bonded. This recess 3a is a recess for a cavity that becomes a cavity C, in which the piezoelectric vibrating reed 4 is housed, when both substrates 2, 3 are stacked up. In addition, the lid substrate 3 is anodically bonded to the base substrate 2 in a state where the recess 3a faces the base substrate 2.

Similar to the lid substrate 3, the base substrate 2 described above is a transparent insulating substrate made of a glass material, for example, soda lime glass. As shown in FIGS. 1 to 4, the base substrate 2 is formed in a plate shape with a size in which it can be stacked up on the lid substrate 3.

A pair of through holes 30 and 31 passing through the base substrate 2 in the thickness direction is formed in this base substrate 2. In this case, the pair of through holes 30 and 31 is formed so as to be settled in the cavity C. When the through holes 30 and 31 of the present embodiment are explained in more detail, one through hole 30 is formed at the position corresponding to the base portion 12 side of the mounted piezoelectric vibrating reed 4, and the other through hole 31 is formed at the position corresponding to the distal end sides of the vibrating arms 10 and 11. In addition, although the through hole with a tapered sectional shape the diameter of which gradually decreases from the bottom surface of the base substrate 2 toward the top surface is described as an example in the present embodiment, a through hole passing through the base substrate 2 straightly may also be used without being limited to this case. In any case, it is necessary that a through hole passes through the base substrate 2.

In addition, a pair of penetration electrodes 32 and 33 formed so as to be embedded in the through holes 30 and 31 is formed in the pair of through holes 30 and 31, respectively. As shown in FIG. 3, these penetration electrodes 32 and 33 are formed by a cylinder 6 and a core portion 7 which are integrally fixed to the through holes 30 and 31 by baking, respectively. The penetration electrodes 32 and 33 serve to maintain the airtightness in the cavity C by completely blocking the through holes 30 and 31 and also to make external electrodes 38 and 39 electrically connected to the lead-out electrodes 36 and 37 which will be described later, respectively.

FIG. 8 is a perspective view of the cylinder.

As shown in FIG. 8, the cylinder 6 is formed by baking glass frit 6a (refer to FIG. 14) in a paste state. The cylinder 6 is formed in a cylindrical shape both ends of which are flat and which has approximately the same thickness as the base substrate 2. In addition, the core portion 7 is disposed at the center of the cylinder 6 so as to pass through the cylinder 6. In addition, in the present embodiment, the outer shape of the cylinder 6 is formed as a conical shape (tapered sectional shape) according to the shapes of the through holes 30 and 31. In addition, as shown in FIG. 4, this cylinder 6 is baked in a state embedded in each of the through holes 30 and 31 and is firmly fixed to each of the through holes 30 and 31.

The core portion 7 is a conductive core which is formed in the cylindrical shape using a metal material. Similar to the cylinder 6, the core portion 7 is formed to have both ends, which are flat, and to have approximately the same thickness as the base substrate 2. In addition, as shown in FIG. 4, when the penetration electrodes 32 and 33 are formed as a finished product, the core portion 7 is formed to have approximately the same thickness as the base substrate 2 as described above. In the manufacturing process, however, the length of the core portion 7 is shorter by 0.02 mm than the original thickness of the base substrate 2 in the manufacturing process (will be described in detail later in an explanation regarding a manufacturing method). In addition, this core portion 7 is located in a central hole 6c of the cylinder 6, and is firmly fixed to the cylinder 6 by baking of the cylinder 6.

In addition, the electrical conductivity of the penetration electrodes 32 and 33 is ensured through the conductive core portion 7.

On the top surface side (bonding surface side to which the lid substrate 3 is bonded) of the base substrate 2, a bonding film 35 for anodic bonding and the pair of lead-out electrodes 36 and 37 are patterned by a conductive material (for example, aluminum), as shown in FIGS. 1 to 4. Among them, the bonding film 35 is formed along the edge of the base substrate 2 so as to surround the periphery of the recess 3a formed in the lid substrate 3.

In addition, the pair of lead-out electrodes 36 and 37 is patterned to electrically connect one penetration electrode 32 of the pair of penetration electrodes 32 and 33 to one mount electrode 16 of the piezoelectric vibrating reed 4 and electrically connect the other penetration electrode 33 to the other mount electrode 17 of the piezoelectric vibrating reed 4.

In addition, the bump B is formed on each of the pair of lead-out electrodes 36 and 37, and the piezoelectric vibrating reed 4 is mounted using the bump B. As a result, one mount electrode 16 of the piezoelectric vibrating reed 4 is electrically connected to one penetration electrode 32 through one lead-out electrode 36, and the other mount electrode 17 is electrically connected to the other penetration electrode 33 through the other lead-out electrode 37.

In addition, the external electrodes 38 and 39 electrically connected to the pair of penetration electrodes 32 and 33, respectively, are formed on the bottom surface of the base substrate 2, as shown in FIGS. 1, 3, and 4. That is, one external electrode 38 is electrically connected to the first excitation electrode 13 of the piezoelectric vibrating reed 4 through one penetration electrode 32 and one lead-out electrode 36. In addition, the other external electrode 39 is electrically connected to the second excitation electrode 14 of the piezoelectric vibrating reed 4 through the other penetration electrode 33 and the other lead-out electrode 37.

When operating the piezoelectric vibrator 1 configured in this way, a predetermined driving voltage is applied to the external electrodes 38 and 39 formed on the base substrate 2. Accordingly, since a current can be made to flow to the excitation electrode 15 of the piezoelectric vibrating reed 4 which is formed by the first and second excitation electrodes 13 and 14, the pair of vibrating arms 10 and 11 can vibrate at a predetermined frequency in a direction moving closer to or away from each other. In addition, using the vibration of the pair of vibrating arms 10 and 11, it can be used as a time source, a timing source of a control signal, a reference signal source, and the like.

### (Method of Manufacturing a Piezoelectric Vibrator)

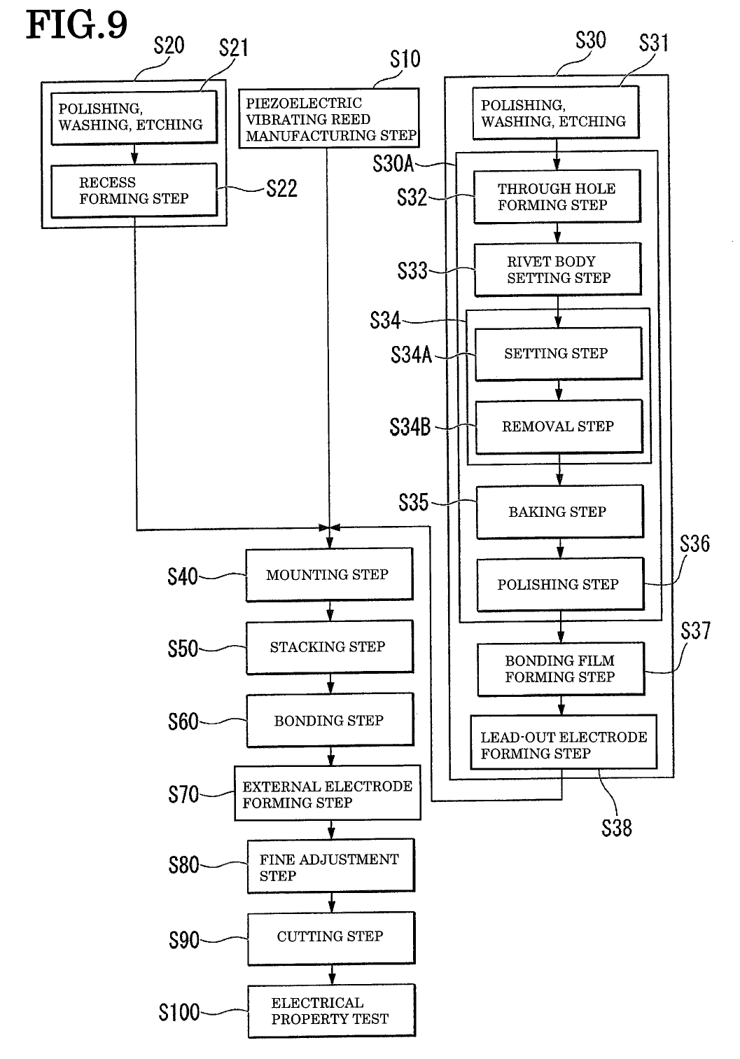

Next, a manufacturing method of manufacturing a plurality of piezoelectric vibrators 1 simultaneously using a wafer 40 for a base substrate, which becomes the base substrates 2, and a wafer for a lid substrate, which becomes the lid substrates 3, will be described below referring to the flow chart shown in FIG. 9.

First, a piezoelectric vibrating reed manufacturing step is performed to manufacture the piezoelectric vibrating reed 4 shown in FIGS. 5 to 7 (S10). In addition, after manufacturing the piezoelectric vibrating reed 4, rough adjustment of a resonance frequency is performed. This is performed by changing the weight by emitting a laser beam onto the rough adjustment film 21a of the weight metal film 21 to evaporate a part of the rough adjustment film 21a. In addition, fine adjustment for adjusting the resonance frequency more accurately is performed after mounting.

Then, a first wafer manufacturing step of manufacturing a wafer for a lid substrate (not shown), which becomes the lid substrates 3 later, is performed until a state immediately before performing anodic bonding (S20). First, soda lime glass is polished up to a predetermined thickness and washed and then the disk-shaped wafer for a lid substrate, from which an affected layer located at the outermost surface has been removed by etching or the like, is formed (S21). Then, a recess forming step of forming the plurality of recesses 3a for a cavity in a matrix by etching or the like is performed on the bonding surface of the wafer for a lid substrate (S22). At this point in time, the first wafer manufacturing step ends.

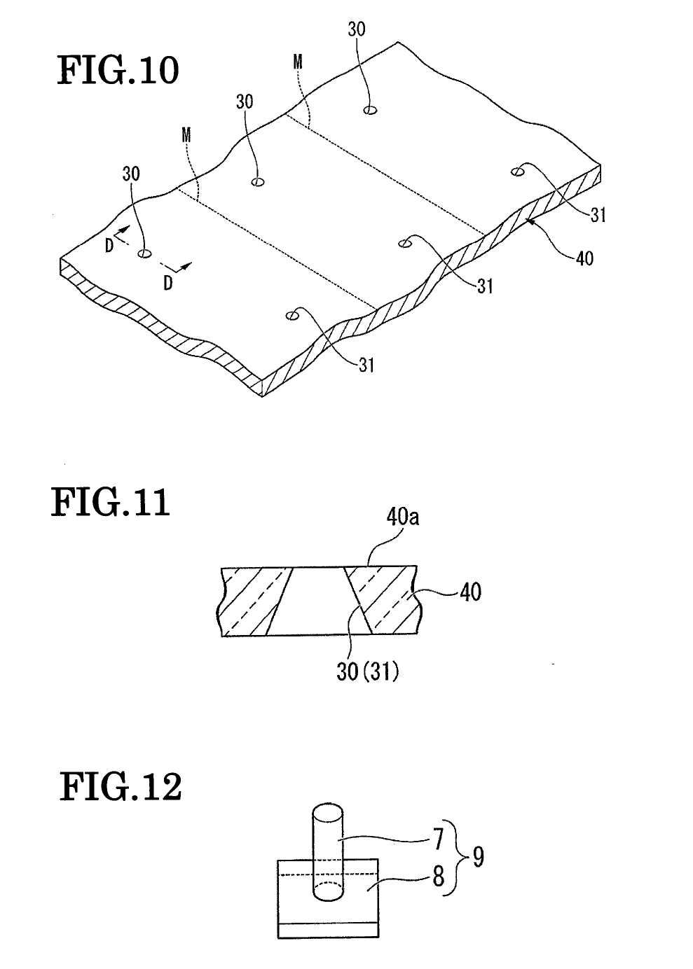

Then, at the same time as the above step or at a timing before or after the above step, a second wafer manufacturing step of manufacturing the wafer 40 for a base substrate (refer to FIG. 10), which becomes the base substrates 2 later, is performed until a state immediately before performing anodic bonding (S30). First, soda lime glass is polished up to a predetermined thickness and washed and then the disk-shaped wafer 40 for a base substrate, from which an affected layer located at the outermost surface was removed by etching or the like, is formed (S31). Then, a penetration electrode forming step of forming a plurality of pairs of penetration electrodes 32 and 33 in the wafer 40 for a base substrate is performed (S30A).

FIG. 10 is a process view showing a penetration electrode forming step and is a perspective view of a wafer for a base substrate. In addition, FIG. 11 is a sectional view taken along the line D-D of FIG. 10.

Here, the penetration electrode forming step (S30A) will be described in detail.

First, as shown in FIGS. 10 and 11, a through hole forming step (S32) of forming a plurality of pairs of through holes 30 and 31 passing through the wafer 40 for a base substrate is performed. In addition, the dotted line M shown in FIG. 10 indicates a cutting line which is cut in a cutting step performed later. This step is performed from the bottom surface side of the wafer 40 for a base substrate using a sandblasting method or pressing, for example. As a result, as shown in FIG. 11, the through holes 30 and 31 with a tapered sectional shape the diameter of which gradually decreases from the bottom surface of the wafer 40 for a base substrate toward the top surface can be formed. In addition, a plurality of pairs of through holes 30 and 31 is formed so as to be settled in the recess 3a, which is formed in the wafer 40 for a lid substrate, when both the wafers 40 are stacked up later. Furthermore, the pair of through holes 30 and 31 is formed such that one through hole 30 is located at the base portion 12 side of the piezoelectric vibrating reed 4 and the other through hole 31 is located at the distal end side of the vibrating arms 10 and 11.

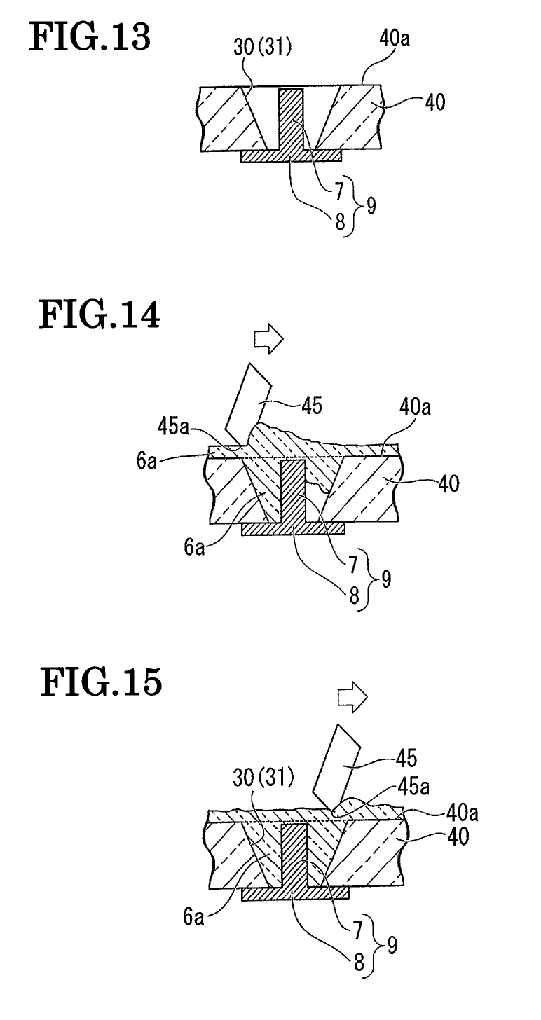

FIG. 12 is a perspective view of a rivet body. In addition, FIGS. 13 to 20 are sectional views of a wafer for a base substrate equivalent to FIG. 11 and are process views for explaining a penetration electrode forming step.

Then, a rivet body setting step of disposing the core portion 7 of a rivet body 9 in the plurality of through holes 30 and 31 is performed (S33). In this case, the conductive rivet body 9 having a plate-shaped base portion 8 and the core portion 7, which is formed along the direction approximately perpendicular to the surface of the base portion 8 from the base portion 8 and with a length shorter by 0.02 mm than the thickness of the wafer 40 for a base substrate and whose distal end is formed flat, is used as the rivet body 9, as shown in FIG. 12. In addition, the core portion 7 is inserted until the surface of the base portion 8 of the rivet body 9 comes in contact with the wafer 40 for a base substrate, as shown in FIG. 13. Here, it is necessary to dispose the rivet body 9 such that the axial direction of the core portion 7 and the axial direction of the through holes 30 and 31 are approximately equal. However, since the rivet body 9 in which the core portion 7 is formed on the base portion 8 is used, it is possible to match the axial direction of the core portion 7 to the axial direction of the through holes 30 and 31 with a simple operation of pushing the base portion 8 until the base portion 8 comes in contact with the wafer 40 for a base substrate. Accordingly, the workability in the rivet body setting step can be improved.

Then, into the through holes 30 and 31 in which the rivet body 9 is set, a filling step of filling the paste-state glass frit 6a into the through holes 30 and 31 is performed (S34).

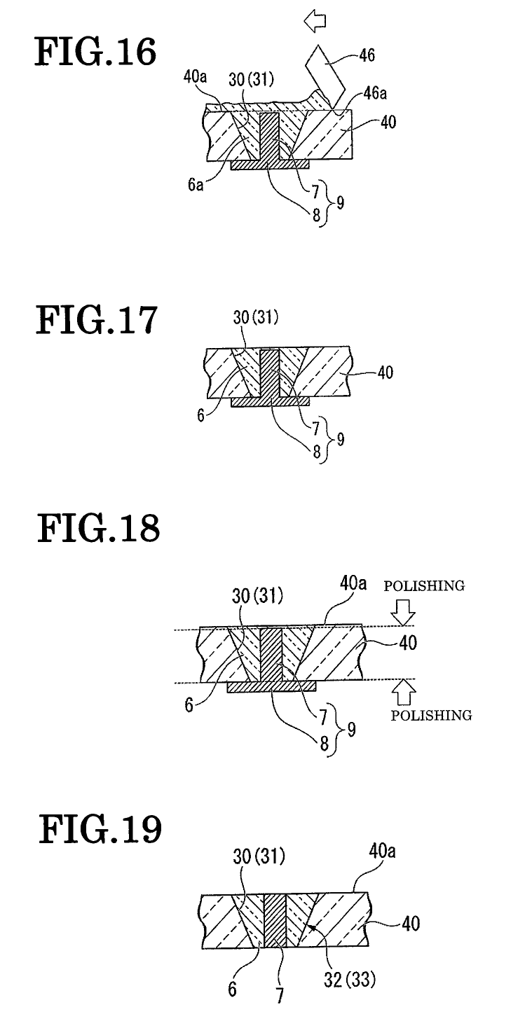

In the filling step (S34), a setting step (first scanning step) of filling the paste-state glass frit 6a into the through holes 30 and 31 is performed first (S34A). In this setting step, the glass frit 6a is filled in the through holes 30 and 31 by scanning a resin squeegee along a surface 40a of the wafer 40 for a base substrate in a chamber of a vacuum screen printer maintained under the decompressed atmosphere (both not shown). In addition, the vacuum screen printer of the present embodiment includes a first squeegee 45 (refer to FIG. 14) and a second squeegee 46 (refer to FIG. 16) with the same shape and are held so that they can be scanned in the facing directions by a moving mechanism (not shown).

In the setting step (S34A), first, the wafer 40 for a base substrate is transported into the chamber and the glass frit 6a is applied into the through holes 30 and 31. In this case, a large amount of glass frit 6a is applied so that the glass frit 6a is reliably filled into the through holes 30 and 31. Accordingly, the glass frit 6a is also applied on the surface 40a of the wafer 40 for a base substrate. Then, by decompressing the inside of the chamber up to about 1 torr, the glass fit 6a is degassed and bubbles included in the glass frit 6a are removed. In addition, the glass frit 6a used in the present embodiment is formed by mixing a glass material or a resin material, such as ethyl cellulose for giving thixotropy, in an organic solvent, such as butyl carbitol.

As shown in FIG. 14, in a state where the inside of the chamber is decompressed, the first squeegee 45 is scanned from one end side of the wafer 40 for a base substrate in the radial direction toward the other end side in a state where the glass frit 6a is interposed between a tip 45a of the first squeegee 45 and the wafer 40 for a base substrate (refer to arrows in FIGS. 14 and 15). In this case, the first squeegee 45 is scanned so that the surface direction of the wafer 40 for a base substrate and the scanning surface of the first squeegee 45 are parallel in a state where the contact angle (attack angle) between the first squeegee 45 and the wafer 40 for a base substrate is set to about 5° to 60°.

Here, in the present embodiment, in order to improve the fluidity of the glass frit 6a, it is preferable to set the scanning speed of the first squeegee 45 and the pressing force acting on the glass frit 6a from the tip 45a of the first squeegee 45 such that the viscosity of the glass frit 6a is equal to or larger than 10 Pa·s and equal to or smaller than 200 Pa·s. In order to set the glass frit 6a to have the above-described desired viscosity, the scanning speed of the first squeegee 45 is preferably set to be equal to or larger than 1 mm/sec and equal to or smaller than 10 mm/sec, and the pressing force (line pressure) acting on the glass frit 6a from the tip 45a of the first squeegee 45 is preferably set to be equal to or larger than 1 mg/mm and equal to or smaller than 1000 mg/mm. If the scanning speed of the first squeegee 45 is set to be smaller than 1 mm/sec and the pressing force is set to be smaller than 1 mg/mm, the above-described desired viscosity cannot be obtained. Therefore, this is not preferable as there is a possibility that the glass frit 6a will not smoothly enter the through holes 30 and 31. On the other hand, setting the scanning speed of the first squeegee 45 to be larger than 10 mm/sec is not preferable as it is difficult to make the glass frit 6a be swept away into the through holes 30 and 31. In addition, setting the pressing force to be larger than 1000 mg/mm is not preferable as the wafer 40 for a base substrate is overloaded.

In addition, in the present embodiment, the viscosity of the glass frit 6a is set to 60 Pa·s, for example. In accordance with this, the scanning speed of the first squeegee 45 is set to about 10 mm/sec and the pressing force is set to about 73 mg/mm.

In addition, if the first squeegee 45 is scanned according to the above-described conditions, the glass frit 6a flows to be swept away along the scanning direction (refer to the arrow in FIG. 14) of the first squeegee 45 by the tip 45a of the first squeegee 45. As a result, the glass frit 6a is leveled on the wafer 40 for a base substrate as shown in FIG. 15. In addition, when scanning the first squeegee 45 along the opening edge of the through holes 30 and 31, the glass frit 6a near the opening edge flows to be swept away into the through holes 30 and 31 by the tip 45a of the first squeegee 45. As a result, the glass fit 6a is filled into the through holes 30 and 31 without a gap. In addition, since the base portion 8 is in contact with the surface 40a of the wafer 40 for a base substrate, the glass frit 6a can be reliably filled into the through holes 30 and 31 without the glass frit 6a overflowing from the bottom surface side of the wafer 40 for a base substrate.

In addition, since the base portion 8 is formed in a flat shape, the wafer 40 for a base substrate is stabilized without shaking even if the wafer 40 for a base substrate is placed on a flat surface, such as a desk, until a baking step performed later after the setting step. Also from this point of view, the workability can be improved.

If the glass frit 6a is baked after the setting step (S34A) is performed, it takes a great deal of time to perform a subsequent polishing step. For this reason, a removal step (S34B: second scanning step) of removing the superfluous glass frit 6a before baking is performed.

Meanwhile, as described above, the glass frit 6a of the present embodiment is formed by mixing a glass material or a resin material in an organic solvent. In this case, if the glass frit 6a is exposed for a long period of time under the extremely decompressed atmosphere (for example, less than 20 torr), there is a possibility that the organic solvent of the glass frit 6a may be removed by evaporation. As a result, since the viscosity of the glass frit 6a remaining at the outside of through holes 30 and 31 increases, it becomes difficult to remove the glass frit 6a in the removal step.

For this reason, in the removal step (S34B), the pressure in the chamber is increased compared with that in the setting step (S34A). The pressure in the chamber in this case is preferably set as a pressure at which the organic solvent of the glass frit 6a does not evaporate. For example, it is preferable that the pressure in the chamber is increased up to about 30 torr. As a result, the removal step (S34B) can be performed while preventing the evaporation of the glass frit 6a.

Then, after increasing the pressure of the inside of the chamber, the second squeegee 46 is scanned along the surface 40a of the wafer 40 for a base substrate, as shown in FIG. 16. Specifically, in a state where the tip 46a of the second squeegee 46 is in contact with the surface 40a of the wafer 40 for a base substrate, the second squeegee 46 is scanned in the opposite direction to the scanning direction of the first squeegee 45 according to the same conditions as the scanning conditions of the first squeegee 45 described above, that is, along the one end side from the other end side of the wafer 40 for a base substrate in the radial direction (refer to the arrow in FIG. 16). As a result, the second squeegee 46 is scanned such that the glass frit 6a present on the surface 40a of the wafer 40 for a base substrate, which is present outside the through holes 30 and 31, is saved by the tip 46a of the second squeegee 46.

In this way, it is possible to remove the superfluous glass frit 6a present on the surface 40a of the wafer 40 for a base substrate by the simple operation, as shown in FIG. 17. Moreover, in the present embodiment, the length of the core portion 7 of the rivet body 9 is shorter by 0.02 mm than the thickness of the wafer 40 for a base substrate. Accordingly, when the second squeegee 46 passes upper portions of the through holes 30 and 31, the tip 45a of the squeegee 45 and the tip of the core portion 7 are not in contact with each other. As a result, it is possible to suppress a situation where the core portion 7 is inclined.

Then, a baking step of baking the embedded glass frit 6a at a predetermined temperature is performed (S35). As a result, the through holes 30 and 31, the glass frit 6a embedded in the through holes 30 and 31, and the rivet body 9 disposed in the glass frit 6a are secured to each other. When performing the baking, each base portion 8 is baked. Accordingly, in a state where the axial direction of the core portion 7 and the axial direction of the through holes 30 and 31 are approximately equal, both of them can be integrally fixed. When the glass frit 6a is baked, it solidifies into the cylinder 6. Then, as shown in FIG. 18, a polishing step of polishing the base portion 8 of the rivet body 9 to remove it is performed after baking (S36). Accordingly, since the base portion 8 serving to determine the positions of the cylinder 6 and the core portion 7 can be removed, only the core portion 7 can be left inside the cylinder 6.

In addition, the surface 40a of the wafer 40 for a base substrate is polished at the same time so as to become a flat surface. Then, the surface 40a is polished until the tip of the core portion 7 is exposed. As a result, as shown in FIG. 19, it is possible to obtain a plurality of pairs of penetration electrodes 32 and 33 in which the cylinder 6 and the core portion 7 are integrally fixed.

In addition, when forming the penetration electrodes 32 and 33, the penetration electrodes 32 and 33 are formed by the cylinder 6 made of a glass material and the conductive core portion 7 without using paste for a conductive portion, differing with convention. If paste is used for a conductive portion, an organic matter contained in the paste evaporates at the time of baking. As a result, the volume of the paste is noticeably reduced compared with that before the baking. For this reason, if only paste is embedded in the through holes 30 and 31, a large recess is generated on the surface of the paste after baking. In the present embodiment, however, a reduction in the volume of a conductive portion can be prevented as the metallic core portion 7 is used for the conductive portion.

As a result, the surface of the wafer 40 for a base substrate becomes approximately even with both ends of the cylinder 6 and the core portion 7. That is, the surface of the wafer 40 for a base substrate becomes approximately even with the surfaces of the penetration electrodes 32 and 33. In addition, the penetration electrode forming step (S30A) ends after performing the polishing step (S36).

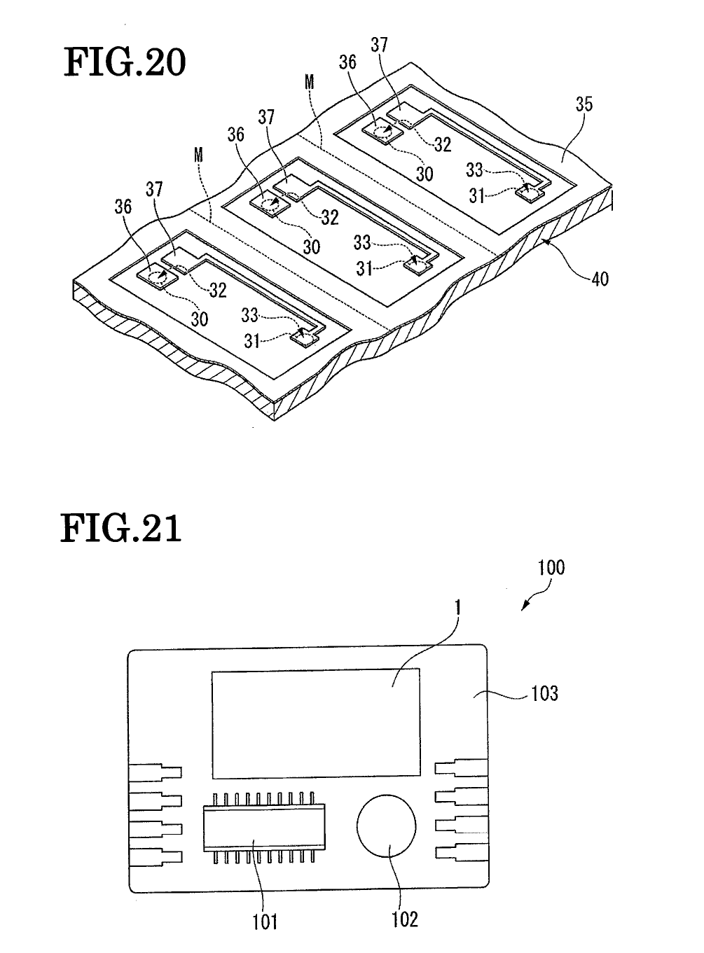

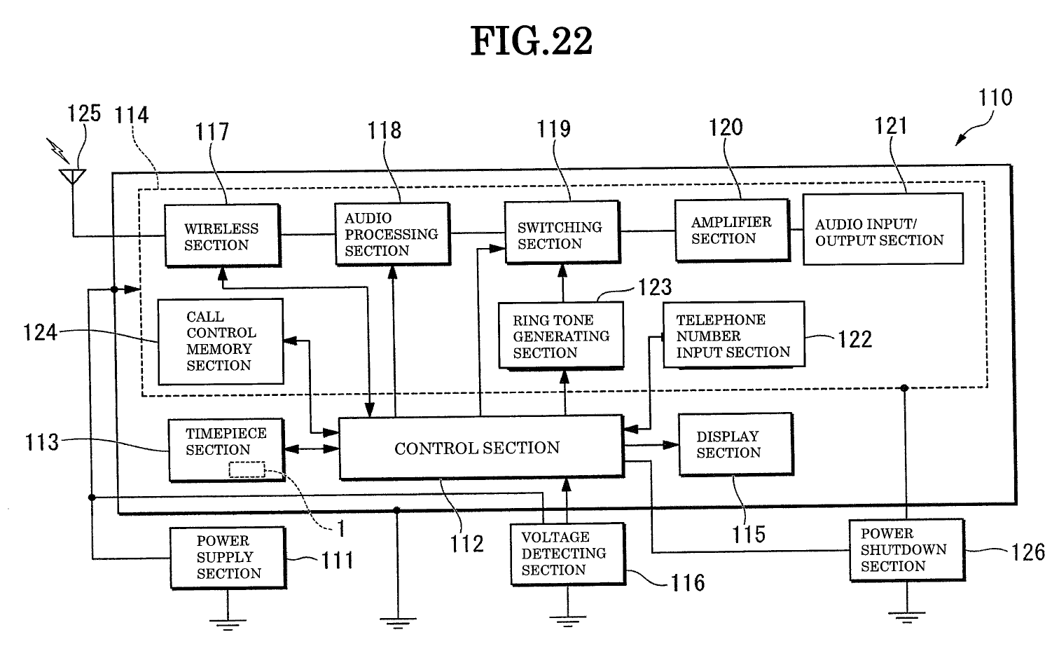

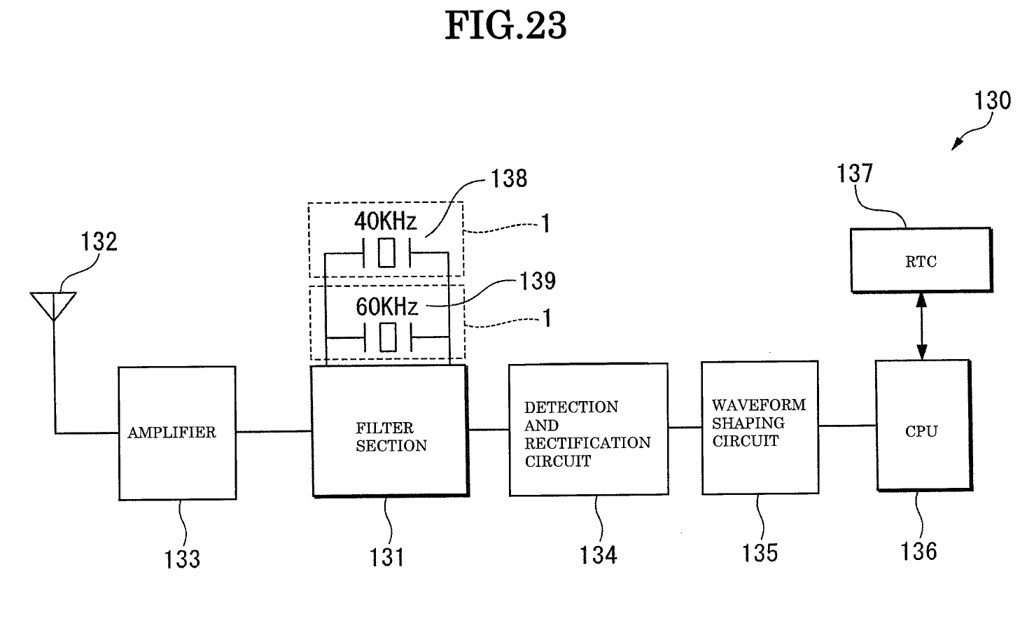

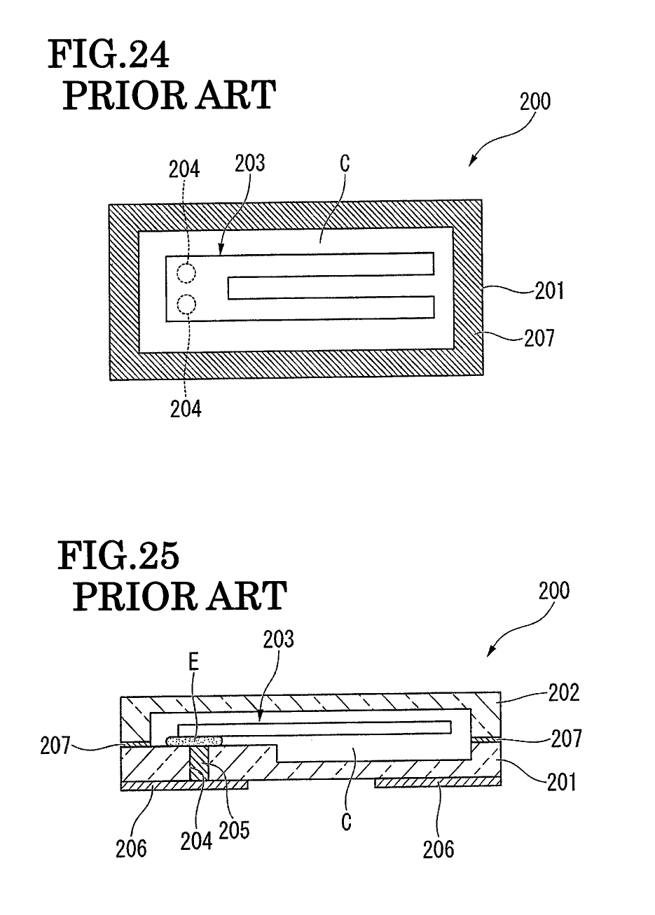

FIG. 20 is a view showing a state where a bonding film and a lead-out electrode are patterned on the top surface of a wafer for a base substrate. Moreover, in the drawing, the dotted line M indicates the outline of the piezoelectric vibrator 1.

Then, by patterning a conductive material on the top surface of the wafer 40 for a base substrate, a bonding film forming step of forming the bonding film 35 is performed (S37) and at the same time, a lead-out electrode forming step of forming the plurality of lead-out electrodes 36 and 37 electrically connected to the pair of penetration electrodes 32 and 33, respectively, is performed (S38), as shown in FIG. 20.

In particular, the penetration electrodes 32 and 33 become approximately even with the top surface of the wafer 40 for a base substrate, as described above. Accordingly, the electrodes 36 and 37 patterned on the top surface of the wafer 40 for a base substrate are in close contact with the penetration electrodes 32 and 33 without generating a gap or the like therebetween. As a result, an electrical connection between one lead-out electrode 36 and one penetration electrode 32 and an electrical connection between the other lead-out electrode 37 and the other penetration electrode 33 can be ensured. At this point in time, the second wafer manufacturing step ends.

Then, a mounting step (S40) of bonding the piezoelectric vibrating reed 4 on the lead-out electrode 36 and 37 of the wafer 40 for a base substrate through the bump B is performed, and then the wafer for a lid substrate is stacked up on the wafer 40 for a base substrate (S50: stacking step).

After the stacking step S50, the two stacked wafers 40 are put into an anodic bonding apparatus (not shown), in which anodic bonding is performed by applying a predetermined voltage in the predetermined temperature atmosphere, and a bonded wafer body is formed accordingly (S60: bonding step). Meanwhile, when performing anodic bonding, the through holes 30 and 31 formed in the wafer 40 for a base substrate are completely blocked by the penetration electrodes 32 and 33. Accordingly, the airtightness in the cavity C is not influenced by the through holes 30 and 31. In addition, since the cylinder 6 and the core portion 7 are fixed by baking and they are firmly fixed to the through holes 30 and 31, the airtightness in the cavity C can be reliably maintained.

Then, after the anodic bonding described above ends, an external electrode forming step of forming a plurality of pairs of external electrodes 38 and 39 electrically connected to the pair of penetration electrodes 32 and 33, respectively, by patterning a conductive material on the bottom surface of the wafer 40 for a base substrate is performed (S70).

In particular, also in the case of performing this step, the penetration electrodes 32 and 33 are approximately even with the bottom surface of the wafer 40 for a base substrate, similar to the case when forming the lead-out electrodes 36 and 37. Accordingly, the patterned external electrodes 38 and 39 are in close contact with the penetration electrodes 32 and 33 without generating a gap or the like therebetween. As a result, electrical connections between the external electrodes 38 and 39 and the penetration electrodes 32 and 33 can be ensured.

Then, a fine adjustment step of setting the frequency of each piezoelectric vibrator 1, which is sealed in the cavity C, to fall within a predetermined range by fine adjustment in a state of a bonded wafer body is performed (S80).

After the fine adjustment of a frequency ends, a cutting step of cutting the bonded wafer body into pieces by cutting it along the cutting line M is performed (S90).

Then, testing of internal electrical properties (S100) is performed, and the manufacturing of the piezoelectric vibrator 1 ends.

Thus, in the present embodiment, in the filling step (S34), the paste-state glass frit 6a is filled in the through holes 30 and 31 under the decompressed atmosphere.

According to this configuration, since the glass frit 6a is degassed by performing the filling step (S34) under the decompressed atmosphere, bubbles included in the glass frit 6a can be removed. As a result, bubbles are not present in the glass frit 6a, and the air is not present in the through holes 30 and 31. Therefore, by making the glass frit 6a be swept away by the first squeegee 45 in the setting step (S34A), the glass frit 6a can be smoothly filled into the through holes 30 and 31 compared with the case of filling through holes with the glass frit 6a in the atmosphere as in the related art. As a result, the glass frit 6a can be filled into the through holes 30 and 31 without a gap.

In addition, by baking the glass frit 6a in this state, the through holes 30 and 31 can be sealed without a gap by the cylinder 6 formed after baking. As a result, the airtightness in the cavity C can be satisfactorily maintained. In addition, since a volume reduction or deformation after baking tends not to occur, the core portion 7 can be firmly fixed at a predetermined position. Accordingly, the penetration electrodes 32 and 33 with desired sizes can be formed. Therefore, the external electrodes 38 and 39 come in close contact with the penetration electrodes 32 and 33, respectively, without generating a gap therebetween. As a result, since breakage of the external electrodes 38 and 39 formed to cover the penetration electrodes 32 and 33 can be prevented, electrical connections between the piezoelectric vibrating reed 4 and the external electrodes 38 and 39 through the penetration electrodes 32 and 33 can be ensured.

In addition, since the air remaining in the through holes 30 and 31 does not leak to the cavity C after baking of the glass frit 6a, the vibration characteristic of the piezoelectric vibrator 1 is not deteriorated.

Therefore, a highly reliable piezoelectric vibrator 1 which is small and excellent in the vibration characteristic can be collectively manufactured on the wafer with an improved yield.

Moreover, in the present embodiment, since thixotropy is given to the glass frit 6a, the viscosity of the glass frit 6a can be reduced by performing the setting step (S34A) under the above-described conditions in the chamber. As a result, the fluidity of the glass frit 6a can be improved. Therefore, it is possible to make the glass fit 6a be swept away more smoothly into the through holes 30 and 31.

### (Oscillator)

Next, an embodiment of an oscillator related to the present invention will be described referring to FIG. 15.

An oscillator 100 of the present embodiment includes the piezoelectric vibrator 1 configured as a vibrator electrically connected to an integrated circuit 101, as shown in FIG. 15. This oscillator 100 includes a substrate 103 on which an electronic component 102, such as a capacitor, is mounted. The above-described integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, the piezoelectric vibrating reed 4 in the piezoelectric vibrator 1 vibrates when a voltage is applied to the piezoelectric vibrator 1. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as a vibrator.

In addition, by selectively setting the configuration of the integrated circuit 101, for example, an RTC (Real Time Clock) module, according to demand, it is possible to add a function of controlling the operation date or time of the corresponding device or an external device or of providing the time or calendar in addition to a single functional oscillator for a timepiece.

As described above, since the oscillator 100 of the present embodiment includes the high-quality piezoelectric vibrator 1, the oscillator 100 itself can also similarly have high quality. In addition to this, it is possible to obtain a highly precise frequency signal which is stable over a long period of time.

### (Electronic Device)

Next, an embodiment of an electronic device related to the present invention will be described with reference to FIG. 16. In addition, a portable information device 110 including the above piezoelectric vibrator 1 will be described as an example of the electronic device. First, the portable information device 110 of the present embodiment is represented by a mobile phone, for example, and has been developed and improved from a wristwatch in the related art. The portable information device 110 is similar to a wristwatch in its external appearance, and a liquid crystal display is disposed in a portion equivalent to a dial pad so that the current time and the like can be displayed on the screen. In addition, when this is used as a communication apparatus, it is possible to remove it from the wrist and to perform the same communication as a mobile phone in the related art through a speaker and a microphone built in an inner portion of the band. Nevertheless, the portable information device 110 is very small and light compared with a mobile phone in the related art.

Next, the configuration of the portable information device 110 of the present embodiment will be described. As shown in FIG. 16, the portable information device 110 includes the piezoelectric vibrator 1 and a power supply section 111 for supplying power. The power supply section 111 is formed of a lithium secondary battery, for example. A control section 112 which performs various kinds of control, a timepiece section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display the current time. In addition, the control section 112 includes a ROM in which a program is written in advance, a CPU which reads and executes a program written in the ROM, a RAM used as a work area of the CPU, and the like.

The timepiece section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 4 vibrates, and this vibration is converted to an electrical signal due to the piezoelectric property of crystal and is then input to the oscillation circuit as an electrical signal. The output of the oscillation circuit is binarized to be counted by the register circuit and the counter circuit. Then, a signal is transmitted to or received from the control section 112 through the interface circuit, and the current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to the predetermined level. The audio input/output section 121 is formed by a speaker, a microphone, and the like, and amplifies a ring tone or incoming sound or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. In addition, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set in advance as the lowest voltage necessary to operate the communication section 114 stably. For example, it is about 3 V. The control section 112 which has received the notification of a voltage drop from the voltage detecting section 116 disables the operations of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detection section 116 and the control section 112. This message may be a character message, or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 of the present embodiment includes the high-quality piezoelectric vibrator 1, the portable information device itself can also similarly have high quality. In addition to this, it is possible to display highly precise timepiece information which is stable over a long period of time.

Next, an embodiment of a radio-controlled timepiece related to the present invention will be described with reference to FIG. 17.

As shown in FIG. 17, a radio-controlled timepiece 130 of the present embodiment includes the piezoelectric vibrators 1 electrically connected to a filter section 131, and is a timepiece with a function of receiving a standard radio wave including the timepiece information, automatically changing it to the correct time, and displaying it.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the whole of Japan through the two transmission centers.

### (Radio-Controlled Timepiece)

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1.

In the present embodiment, the piezoelectric vibrators 1 include crystal vibrator sections 138 and 139 having resonance frequencies of 40 kHz and 60 kHz, respectively, which are the same frequencies as the carrier frequencies.

In addition, the filtered signal with a predetermined frequency is detected and demodulated by a detection and rectification circuit 134.

Then, the time code is extracted by a waveform shaping circuit 135 and counted by a CPU 136. The CPU 136 reads the information including the current year, the total number of days, the day of the week, the time, and the like. The read information is reflected on an RTC 137, and the correct time information is displayed.

As the carrier wave is 40 kHz or 60 kHz, a vibrator having the tuning fork structure described above is suitable for the crystal vibrator sections 138 and 139.

In addition, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 of the present embodiment includes the high-quality piezoelectric vibrator 1, the radio-controlled timepiece itself can also similarly have high quality. In addition to this, it is possible to count the time precisely and stably over a long period of time.

While the embodiments of the present invention have been described in detail with reference to the drawings, the specific configuration is not limited to the above-described embodiments, and various changes may be made in design without departing from the spirit of the present invention.

For example, although the tuning fork type piezoelectric vibrating reed 4 was mentioned as an example in the embodiment described above, the present invention is not limited to the tuning fork type. For example, when mounting a thickness-shear vibrating reed or an AT vibrating reed in a cavity and electrically connecting these vibrating reeds and an external electrode, a penetration electrode may be formed by the method described above.

In addition, although a two-layer structure type in which the piezoelectric vibrating reed 4 is housed in the cavity C formed between the base substrate 2 and the lid substrate 3 has been described in the above embodiment, the present invention is not limited to this, and a three-layer structure type may also be adopted in which a piezoelectric substrate formed with the piezoelectric vibrating reed 4 is bonded so as to be interposed between the base substrate 2 and the lid substrate 3 from top and bottom sides.

In addition, although the case where the glass fit 6a as a filler is filled between the core portion 7 and through holes 30 and 31 has been described in the above embodiment, the present invention is not limited to this, and it is possible to adopt a configuration in which a conductive material is filled in the through holes 30 and 31 and this itself is used as a penetration electrode. As such a filler, it is possible to use a material including metal particulates and a plurality of glass beads or the above-described conductive paste.

In addition, in the above embodiment, the piezoelectric vibrating reed 4 with a groove in which the groove 18 is formed on both the surfaces of the vibrating arms 10 and 11 has been mentioned as an example of the piezoelectric vibrating reed 4. However, a piezoelectric vibrating reed without the groove 18 may be used. However, since the electric field efficiency between the pair of excitation electrodes 15 can be improved by forming the groove 18 when a predetermined voltage is applied to the pair of excitation electrodes 15, vibration loss can be suppressed. As a result, the vibration characteristic can be further improved. That is, since the CI value (Crystal Impedance) can be further reduced, the performance of the piezoelectric vibrating reed 4 can be further improved. From this point of view, it is preferable to form the groove 18.

In addition, although the piezoelectric vibrating reed 4 was bump-bonded in the above-described embodiment, the present invention is not limited to bump bonding. For example, the piezoelectric vibrating reed 4 may be bonded using a conductive adhesive. However, since the piezoelectric vibrating reed 4 can be floated from the top surface of the base substrate 2 by bump bonding, a minimum vibration gap required for vibration can be naturally ensured. Therefore, bump bonding is preferable.

Since the airtightness in a cavity is maintained and a stable electrical connection between a piezoelectric vibrating reed and an external electrode can be secured, the yield can be improved.

What is claimed is:

1. A method of manufacturing a package capable of sealing an electronic component in a cavity formed between a plurality of substrates bonded to each other, the package manufacturing method comprising:
a penetration electrode forming step of forming a penetration electrode which passes through a first substrate of the plurality of substrates in the thickness direction and which electrically connects the inside of the cavity and the outside of the package to each other,
wherein the penetration electrode forming step includes a through hole forming step of forming a through hole for disposing the penetration electrode in the first substrate and a filling step of filling a filler into the through hole under a decompressed atmosphere.

2. The package manufacturing method according to claim 1,
wherein the filling step includes:
a first scanning step of scanning a first squeegee from one end side of the first substrate to the other end side along a top surface of the first substrate in order to fill the filler into the through hole; and
a second scanning step of scanning a second squeegee from the other end side of the first substrate to the one end side along the top surface of the first substrate in order to remove the filler present outside the through hole, and
the ambient pressure in the second scanning step is set to be higher than that in the first scanning step.

3. The package manufacturing method according to claim 1,
wherein before the filling step, a rivet body setting step of inserting a core portion of a conductive rivet body, which has a plate-shaped base portion and the core portion which extends along a direction perpendicular to a surface of the base portion, into the through hole so that the surface of the base portion is in contact with a bottom surface of the first substrate is set,
in the filling step, the glass frit is filled between the core portion and the through hole using paste-state glass frit as the filler, and
after the filling step, a baking step of baking the glass frit to integrally fix the through hole and the core portion and a polishing step of polishing the base portion and the bottom surface of the first substrate, on which the base portion is disposed, and polishing the top surface of the first substrate so that the core portion is exposed are set.

4. The package manufacturing method according to claim 3,
wherein in the first scanning step, the viscosity of the glass frit is set to be equal to or larger than 10 Pa·s and equal to or smaller than 200 Pa·s.

5. The package manufacturing method according to claim 4,
wherein in the first scanning step, the scanning speed of the squeegee is set to be equal to or larger than 1 mm/sec and equal to or smaller than 50 mm/sec.

6. The package manufacturing method according to claim 4,
wherein in the first scanning step, line pressure acting on the glass frit from the tip of each squeegee is set to be equal to or larger than 1 mg/mm and equal to or smaller than 1000 mg/mm.

7. A piezoelectric vibrator manufactured by the package manufacturing method according to claim 1.

8. An oscillator comprising:
the piezoelectric vibrator according to claim 7, which is electrically connected to an integrated circuit, as a vibrator.

9. An electronic device comprising:
the piezoelectric vibrator according to claim 7 which is electrically connected to a timepiece section.

10. A radio-controlled timepiece comprising:
the piezoelectric vibrator according to claim 7 which is electrically connected to a filter section.
